(19) United States
(12) Patent Application Publication
(10) Pub. No.: US 2025/0063916 A1
(43) Pub. Date: Feb. 20, 2025

(54) DISPLAY DEVICE

(71) Applicant: Samsung Display Co., LTD., Yongin-si (KR)

(72) Inventors: Sangshin LEE, Yongin-si (KR); Yeonju KANG, Yongin-si (KR); Sanghoon KIM, Yongin-si (KR); Jaesuk MOON, Yongin-si (KR); Yuri LEE, Yongin-si (KR)

(21) Appl. No.: 18/787,229

(22) Filed: Jul. 29, 2024

(30) Foreign Application Priority Data
Aug. 16, 2023 (KR) 10-2023-0107073
Jan. 8, 2024 (KR) 10-2024-0003128

(51) Int. Cl. H10K 59/35; H10K 59/80

(52) U.S. Cl. CPC H10K 59/353; H10K 59/351; H10K 59/80522

(57) ABSTRACT

A display device includes a substrate on which unit pixel areas are defined, where the unit pixel areas are arranged in a first direction and a second direction perpendicular to the first direction in a plan view, first to fourth sub-pixels arranged on the substrate in each of the unit pixel areas, where the first and fourth sub-pixels emit light of a first color, the second sub-pixel emits light of a second color and the third sub-pixel emits light of a third color, a bank layer provided with a bank opening defined therein, where the bank opening is surrounded by the first to fourth sub-pixels in the plan view, an intermediate layer disposed on the bank layer, where an intermediate opening is defined in the intermediate layer to overlap the bank opening, and an opposite electrode disposed on the intermediate layer.

This application claims priority to Korean Patent Application No. 10-2023-0107073, filed on Aug. 16, 2023, and Korean Patent Application No. 10-2024-0003128, filed on Jan. 8, 2024, and all the benefits accruing therefrom under 35 U.S.C. § 119, the contents of which in their entirety are herein incorporated by reference.

### BACKGROUND

### 1. Field

One or more embodiments relate to a display device.

### 2. Description of the Related Art

Display devices are devices that visually display data. The display device may include a substrate divided into a display area and a peripheral area. In the display area, a scan line and a data line are insulated from each other and a plurality of sub-pixels may be provided. Also, in the display area, a thin-film transistor and a pixel electrode electrically connected to the thin-film transistor may be provided for each sub-pixel. In addition, in the display area, an opposite electrode may be commonly provided for the sub-pixels. In the peripheral area, various wires for transmitting an electric signal to the display area, a scan driver, a data driver, a controller, and a pad unit may be provided.

Recently, display devices are widely used in various fields. Accordingly, various designs are being attempted to improve the quality of the display devices.

### SUMMARY

One or more embodiments include a display device for realizing a high-quality image by preventing a voltage drop of an opposite electrode.

According to one or more embodiments, a display device includes a substrate, on which unit pixel areas are defined, where the unit pixel areas are arranged in a first direction and a second direction perpendicular to the first direction in a plan view, a first sub-pixel, a second sub-pixel, a third sub-pixel, and a fourth sub-pixel, which are arranged on the substrate in each of the unit pixel areas, where the first sub-pixel emits light of a first color, the second sub-pixel emits light of a second color, the third sub-pixel emits light of a third color, and the fourth sub-pixel emits light of the first color, a bank layer provided with a bank opening defined therein, where the bank opening is surrounded by the first sub-pixel, the second sub-pixel, the third sub-pixel, and the fourth sub-pixel, in the plan view, an intermediate layer disposed on the bank layer, where an intermediate opening is defined in the intermediate layer to overlap the bank opening, and an opposite electrode disposed on the intermediate layer.

In an embodiment, the display device may further include an auxiliary electrode disposed on the substrate, where the opposite electrode may be in contact with the auxiliary electrode through the intermediate opening and the bank opening.

In an embodiment, in the unit pixel areas, the first sub-pixel and the fourth sub-pixel may be arranged adjacent to each other in a third direction crossing the first direction and the second direction, and the second sub-pixel and the third sub-pixel may be arranged adjacent to each other in a fourth direction perpendicular to the third direction.

In an embodiment, the bank opening may be surrounded by the first to fourth sub-pixels arranged in one unit pixel area.

In an embodiment, a shape of at least one of the first to fourth sub-pixels may be obtained by cutting one region adjacent to the bank opening to correspond to a shape of the bank opening.

In an embodiment, areas of second sub-pixels included in the unit pixel areas may be the same as each other, and areas of third sub-pixels included in the unit pixel areas may be the same as each other.

In an embodiment, shapes of second sub-pixels included in the unit pixel areas may be the same as each other.

In an embodiment, the unit pixel areas may include a first unit pixel area, a second unit pixel area, a third unit pixel area, and a fourth unit pixel area, which form imaginary quadrants, and the bank opening may be positioned in an origin portion at which the first to fourth unit pixel areas all contact with each other.

In an embodiment, the second sub-pixel included in the first unit pixel area may have a first shape, and a shape of at least one selected from second sub-pixels respectively included in the second to fourth unit pixel areas may have a shape obtained by rotating the first shape in a certain angle or a shape obtained by reversing the first shape, based on a certain imaginary axis.

In an embodiment, a pixel electrode of the first sub-pixel and a pixel electrode of the fourth sub-pixel may be electrically connected to each other.

In an embodiment, the display device may further include a connecting wire extending in a third direction crossing the first direction and the second direction to connect the pixel electrode of the first sub-pixel and the pixel electrode of the fourth sub-pixel to each other.

In an embodiment, the first color may be red.

In an embodiment, the unit pixel areas may be provided in a lattice shape.

In an embodiment, the display device may further include an input detecting portion disposed on the opposite electrode, and a planarizing portion arranged between the opposite electrode and the input detecting portion, and overlapping the bank opening.

According to one or more embodiments, a display device include a substrate, on which unit pixel areas are defined, where the unit pixel areas are arranged in a first direction and a second direction perpendicular to the first direction in a plan view, an auxiliary electrode disposed on the substrate, a first sub-pixel, a second sub-pixel, a third sub-pixel, and a fourth sub-pixel, which are arranged in each of the unit pixel areas, where the first sub-pixel emits light of a first color, the second sub-pixel emits light of a second color, the third sub-pixel emits light of a third color, and the fourth sub-pixel emits light of the first color, a bank layer provided with a bank opening defined therein, where the bank opening is surrounded by the first sub-pixel, the second sub-pixel, the third sub-pixel, and the fourth sub-pixel, in the plan view, an intermediate layer disposed on the bank layer, where an intermediate opening is defined in the intermediate layer to overlap the bank opening, and an opposite electrode in contact with the auxiliary electrode through the intermediate opening and the bank opening, wherein a shape of at least one selected from the first to fourth sub-pixels is obtained by cutting one region adjacent to the bank opening to correspond to a shape of the bank opening.

In an embodiment, the first sub-pixel and the second sub-pixel may be alternately arranged in the first direction on a first row, and the third sub-pixel and the fourth sub-pixel may be alternately arranged in the first direction on a second row adjacent to the first row.

In an embodiment, the unit pixel areas may include a first unit pixel area, a second unit pixel area, a third unit pixel area, and a fourth unit pixel area, which form imaginary quadrants, and the bank opening may be positioned adjacent to a fourth sub-pixel of the first unit pixel area, a third sub-pixel of the second unit pixel area, a first sub-pixel of the third unit pixel area, and a second sub-pixel of the fourth unit pixel area.

In an embodiment, areas of second sub-pixels included in the unit pixel areas may be the same as each other, and areas of third sub-pixels included in the unit pixel areas may be the same as each other.

In an embodiment, shapes of second sub-pixels included in the unit pixel areas may be the same as each other, and shapes of third sub-pixels included in the unit pixel areas may be the same as each other.

In an embodiment, the display device may further include a connecting wire electrically connected to a pixel electrode of the first sub-pixel and a pixel electrode of the fourth sub-pixel and extending in a third direction crossing the first direction and the second direction diagonally, where a shape of at least one selected from the second sub-pixel and the third sub-pixel, which are adjacent to each other in each of the unit pixel areas, has one region adjacent to the connecting wire cut to correspond to a shape of the bank opening.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating a display device according to an embodiment;

FIG. 2 is an equivalent circuit diagram showing a light-emitting diode and a pixel circuit electrically connected to the light-emitting diode, which are included in a display device, according to an embodiment;

FIG. 3 is a plan view of a portion of a display device, according to an embodiment;

FIG. 4 is a cross-sectional view schematically illustrating a display device taken along line I-I′ of FIG. 3, according to an embodiment;

FIG. 5 is a plan view schematically illustrating a portion of a display device, according to an embodiment;

FIG. 6A is a cross-sectional view schematically illustrating a display device taken along line II-II′ of FIG. 5, according to an embodiment;

FIG. 6B is a cross-sectional view schematically illustrating a display device taken along line II-II′ of FIG. 5, according to another embodiment;

FIG. 7 is a plan view schematically illustrating a portion of a display device, according to an embodiment;

FIG. 8A is a plan view schematically illustrating a portion of a display device, according to an embodiment;

FIG. 8B is a plan view schematically illustrating a portion of a display device, according to an embodiment;

FIG. 8C is a plan view schematically illustrating a portion of a display device, according to an embodiment;

FIG. 9 is a cross-sectional view schematically illustrating a portion of a display device, according to an embodiment;

FIG. 10A is a plan view schematically illustrating a portion of a display device, according to an embodiment; and

FIG. 10B is a plan view schematically illustrating a portion of a display device, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

One or more embodiments will be described below in more detail with reference to the accompanying drawings. Those components that are the same or are in correspondence with each other are rendered the same reference numeral regardless of the figure number, and any repetitive detailed description thereof may be omitted or simplified.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being “on” another layer, area, or element, it can be directly or indirectly formed on the other layer, region, or element. That is, for example, intervening layers, regions, or elements may be present. In contrast, when an element is referred to as being “directly on” another element, there are no intervening elements present.

In the drawings, for convenience of description, sizes of components may be exaggerated or reduced. In other words, because sizes and thicknesses of components in the drawings are arbitrarily illustrated for convenience of explanation, the disclosure is not necessarily limited thereto.

When a certain embodiment may be implemented differently, a specific process order may be performed differently from the described order. For example, two consecutively described processes may be performed substantially at the same time or performed in an order opposite to the described order.

When a layer, region, component, or the like is connected to another layer, region, component, or the like, the layer, the region, the component, or the like may be not only directly connected thereto, but also indirectly connected thereto with an intervening layer, region, component, or the like therebetween. For example, in the specification, when a layer, region, component, or the like is electrically connected to another layer, region, component, or the like, the layer, region, component, or the like may be nor only directly electrically connected thereto, but also indirectly electrically connected thereto with an intervening layer, region, component, or the like therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

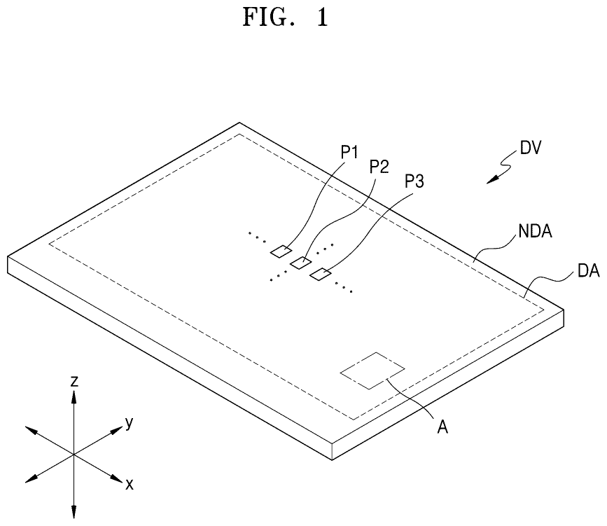

FIG. 1 is a perspective view schematically illustrating a display device DV according to an embodiment.

Referring to FIG. 1, in an embodiment, the display device DV may include a display area DA and a non-display area NDA outside the display area DA. The display device DV may provide, to the display area DA, an image through an array of a plurality of sub-pixels arranged two-dimensionally in an x-y plane. The plurality of sub-pixels include a first sub-pixel P1, a second sub-pixel P2, and a third sub-pixel P3, and hereinafter, for convenience of description, the first sub-pixel P1 may be referred to as a red sub-pixel, the second sub-pixel P2 may be referred to as a green sub-pixel, and the third sub-pixel P3 may be referred to as a blue sub-pixel.

The red sub-pixel, the green sub-pixel, and the blue sub-pixel are respectively areas that emits red light, green light, and blue light, and the display device DV may provide an image by using light emitted from the sub-pixels.

The non-display area NDA is an area where an image is not provided, and may entirely surround the display area DA. A driver or a main voltage line for providing an electric signal or power to pixel circuits may be arranged in the non-display area NDA. A pad that is an area to which an electronic device or a printed circuit board may be electrically connected may be arranged in the non-display area NDA.

In an embodiment, as shown in FIG. 1, the display area DA may have a shape of a polygon including a quadrangle. In an embodiment, for example, the display area DA may have a shape of a rectangle in which a horizontal length is greater than a vertical length, a shape of a rectangle in which a horizontal length is less than a vertical length, or a shape of a square. Alternatively, the display area DA may have any other shape such as an oval or a circle.

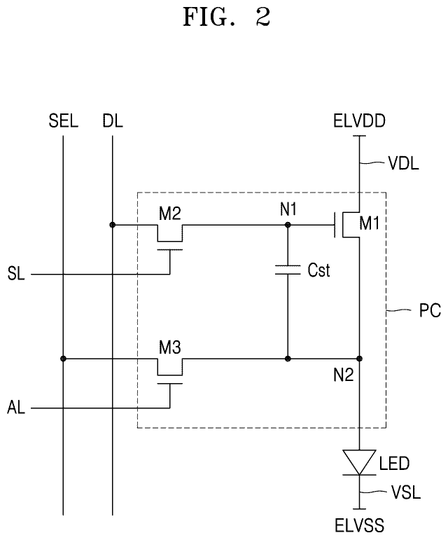

FIG. 2 is an equivalent circuit diagram showing a light-emitting diode LED and a pixel circuit PC electrically connected to the light-emitting diode LED, which are included in a display device, according to an embodiment.

Referring to FIG. 2, the light-emitting diode LED, for example, a pixel electrode (e.g., an anode) of the light-emitting diode LED, may be connected to the pixel circuit PC, and an opposite electrode (e.g., a cathode) of the light-emitting diode LED may be connected to a common voltage line VSL that provides a common power voltage ELVSS. The light-emitting diode LED may emit light in luminance corresponding to the amount of currents supplied from the pixel circuit PC.

The light-emitting diode LED may include an organic light-emitting diode including an organic material. According to another embodiment, the light-emitting diode LED may include an inorganic light-emitting diode including an inorganic material. The inorganic light-emitting diode may include a p-n junction diode including inorganic semiconductor-based materials. When a voltage is applied to the p-n junction diode in a forward direction, holes and electrons are injected, and energy generated by recombination of the holes and electrons is converted into light energy, and thus, light of a certain color may be emitted. The inorganic light-emitting diode may have a width of several to hundreds of micrometers or several to hundreds of nanometers. According to some embodiments, the light-emitting diode LED may include a light-emitting diode including a quantum dot. As described above, an emission layer of the light-emitting diode LED may include an organic material, include an inorganic material, include a quantum dot, include an organic material and a quantum dot, or include an inorganic material and a quantum dot.

The pixel circuit PC may control the amount of currents flowing to the common power voltage ELVSS from a driving power voltage ELVDD through the light-emitting diode LED, in response to a data signal. The pixel circuit PC may include a driving transistor M1, a switching transistor M2, a sensing transistor M3, and a storage capacitor Cst.

Each of the driving transistor M1, the switching transistor M2, and the sensing transistor M3 may include an oxide semiconductor thin-film transistor including a semiconductor layer including an oxide semiconductor, or a silicon semiconductor thin-film transistor including a semiconductor layer including polysilicon. According to a type of a transistor, a first electrode may be one of a source electrode and a drain electrode, and a second electrode may be another of the source electrode and the drain electrode.

A first electrode of the driving transistor M1 may be connected to a driving voltage line VDL supplying the driving power voltage ELVDD and a second electrode thereof may be connected to a first electrode of the light-emitting diode LED. A gate electrode of the driving transistor M1 may be connected to a first node N1. The driving transistor M1 may control the amount of currents flowing through the light-emitting diode LED from the driving power voltage ELVDD, in response to a voltage of the first node N1.

A first electrode of the switching transistor M2 may be connected to a data line DL and a second electrode thereof may be connected to the first node N1. A gate electrode of the switching transistor M2 may be connected to a scan line SL. The switching transistor M2 may be turned on when a scan signal is supplied to the scan line SL and electrically connect the data line DL and the first node N1 to each other.

The sensing transistor M3 may be an initialization transistor and/or a sensing transistor. A first electrode of the sensing transistor M3 may be connected to a second node N2 and a second electrode thereof may be connected to a sensing line SEL. A gate electrode of the sensing transistor M3 may be connected to a control line AL.

The storage capacitor Cst may be connected between the first node N1 and the second node N2. In an embodiment, for example, a first capacitor electrode of the storage capacitor Cst may be connected to the gate electrode of the driving transistor M1, and a second capacitor electrode of the storage capacitor Cst may be connected to a pixel electrode of the light-emitting diode LED.

In an embodiment, as shown in FIG. 2, the driving transistor M1, the switching transistor M2, and the sensing transistor M3 may each be a n-channel metal oxide semiconductor (NMOS), but the disclosure is not limited thereto. In an embodiment, for example, at least one selected from the driving transistor M1, the switching transistor M2, or the sensing transistor M3 may be provided as a p-channel metal oxide semiconductor (PMOS).

An embodiment where the pixel circuit PC includes three transistors is illustrated in FIG. 2, but the disclosure is not limited thereto. In an embodiment, the pixel circuit PC may include four or more transistors.

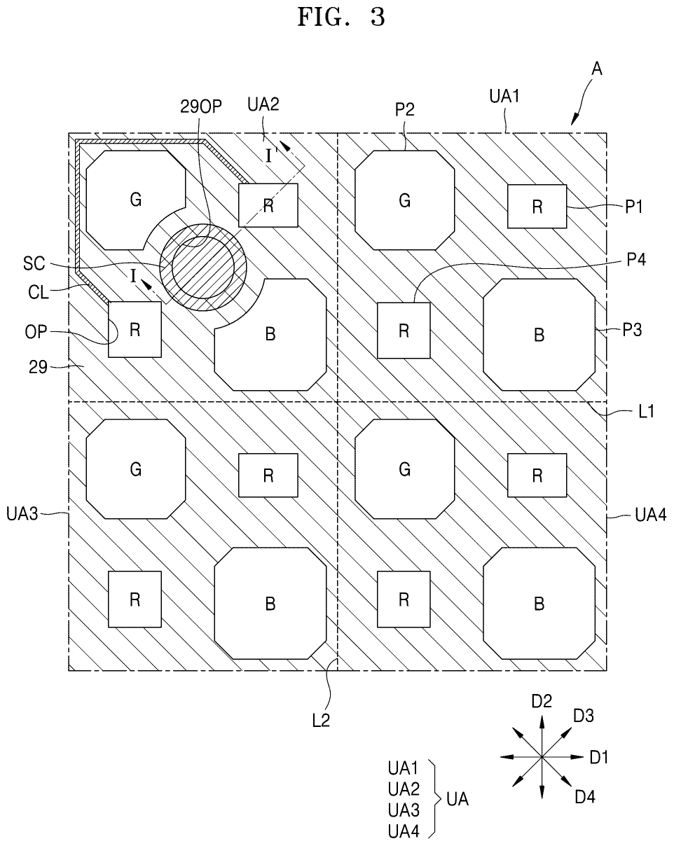

FIG. 3 is a plan view of a portion of a display device, according to an embodiment, wherein a portion A of the display device DV of FIG. 1 is schematically illustrated.

Referring to FIG. 3 together with FIG. 1, in an embodiment, a plurality of sub-pixels may be arranged in the display area DA of the display device DV. In the disclosure, the sub-pixel denotes an emission region realizing an image in a minimum unit. In an embodiment where an organic light-emitting diode is employed as a display element, the emission region may be defined by an opening of a bank layer.

Unit pixel areas UA may be defined in a first direction (e.g., a direction D1) and a second direction (e.g., a direction D2) in the display area DA of the display device DV, and unit pixels may be arranged in the unit pixel area UA. The unit pixels may include the first sub-pixel P1, the second sub-pixel P2, the third sub-pixel P3, and a fourth sub-pixel P4. The first sub-pixel P1 and the fourth sub-pixel P4 may be pixels that emit light of a same color.

According to an embodiment, the first sub-pixel P1 and the fourth sub-pixel P4 may be a red pixel that emits light of a red color, the second sub-pixel P2 may be a green pixel that emits light of a green color, and the third sub-pixel P3 may be a blue pixel that emits light of a blue color. The first sub-pixel P1, the second sub-pixel P2, the third sub-pixel P3, and the fourth sub-pixel P4 may each include the light-emitting diode LED of FIG. 2 that is a display element, and the pixel circuit PC of FIG. 2 to which the light-emitting diode LED is connected. According to an embodiment, the first sub-pixel P1 and the fourth sub-pixel P4 may be driven by a pixel circuit PC substantially the same as that shown in FIG. 2.

The first sub-pixel P1, the second sub-pixel P2, the third sub-pixel P3, and the fourth sub-pixel P4 may be arranged in a certain pattern according to a predetermined rule, in the unit pixel area UA. According to an embodiment, the unit pixel area UA may be a square. A size and shape of an emission region of the light-emitting diode LED is defined by a pixel opening OP of a bank layer 29, and the emission region is a region where an emission layer of the light-emitting diode LED is arranged. Accordingly, in the disclosure, an arrangement (placement) of pixels may denote an arrangement (placement) of display elements, an arrangement (placement) of pixel electrodes, or an arrangement (placement) of emission regions. In the disclosure, a size (area) of a pixel may denote a size (area) of an emission region or a size (area) of the pixel opening OP of the bank layer 29.

Referring to FIG. 3, each unit pixel area UA may include the first to fourth sub-pixels P1 to P4. The unit pixel areas UA may include a first unit pixel area UA1, a second unit pixel area UA2, a third unit pixel area UA3, and a fourth unit pixel area UA4, which form imaginary quadrants. The imaginary quadrant may be formed by a horizontal axis L1 extending in the first direction (e.g., the direction D1) and a vertical axis L2 extending in the second direction (e.g., the direction D2). The first unit pixel area UA1 may correspond to a first quadrant, the second unit pixel area UA2 may correspond to a second quadrant, the third unit pixel area UA3 may correspond to a third quadrant, and the fourth unit pixel area UA4 may correspond to a fourth quadrant. Each of the first to fourth unit pixel areas UA1 to UA4 may include the first to fourth sub-pixels P1 to P4.

In the unit pixel area UA, the first sub-pixel P1 and the second sub-pixel P2 may be adjacently arranged in the first direction (direction D1), and the third sub-pixel P3 and the fourth sub-pixel P4 may be adjacently arranged in the first direction (direction D1). The first sub-pixel P1 and the third sub-pixel P3 may be adjacently arranged in the second direction (direction D2) and the second sub-pixel P2 and the fourth sub-pixel P4 may be adjacently arranged in the second direction (direction D2). In an embodiment, the first sub-pixel P1 and the fourth sub-pixel P4 may be adjacently arranged in a third direction (direction D3) and the second sub-pixel P2 and the third sub-pixel P3 may be adjacently arranged in a fourth direction (direction D4). Alternatively, the first sub-pixel P1 and the fourth sub-pixel P4 may be adjacently arranged in the fourth direction (direction D4), and the second sub-pixel P2 and the third sub-pixel P3 may be adjacently arranged in the third direction (direction D3). In the disclosure, “in the unit pixel area UA” may denote “in one unit pixel area UA”. Embodiments are not limited by the above-described pixel arrangement. In an embodiment, for example, the plurality of sub-pixels may be arranged in any form, such as a mosaic arrangement structure, a stripe structure, or a delta arrangement structure.

In an embodiment, the first sub-pixel P1 and the fourth sub-pixel P4 in the unit pixel area UA may share a same pixel circuit. In the unit pixel area UA, the first sub-pixel P1 and the fourth sub-pixel P4 may be substantially one pixel but include divided emission regions. According to an embodiment, an emission region of a pixel having a smallest emission region, from among a pixel that emits red light, a pixel that emits green light, and a pixel that emits blue light, may be divided into two or more parts. Accordingly, in the unit pixel area UA, a sum of sizes of the first sub-pixel P1 and the fourth sub-pixel P4 may be less than a size of the second sub-pixel P2 or a size of the third sub-pixel P3. However, an embodiment is not limited thereto, and a pixel in which an emission region is divided into two or more parts may be selected as desired. In an embodiment, for example, an entire size of an emission region of a pixel in which the emission region is divided may be greater than a size of an emission region of each of the remaining sub-pixels.

According to an embodiment, an auxiliary electrode SC may be arranged in the display area DA. The auxiliary electrode SC may be provided in an area (hereinafter, a non-pixel area) where the first to fourth sub-pixels P1 to P4 are not arranged, among the display area DA. The auxiliary electrode SC may be a wire that applies or transmits the common power voltage ELVSS (see FIG. 2).

The auxiliary electrode SC may have a certain shape and arranged in the non-pixel area in the unit pixel area UA. In an embodiment, as shown in FIG. 3, the shape of the auxiliary electrode SC may be a circle in a plan view, but an embodiment is not limited thereto. The auxiliary electrode SC may have any shape, such as an oval, a quadrangle, or the like. Alternatively, the auxiliary electrodes SC may extend in the first direction (e.g., direction D1 or direction D3) in the non-pixel area, and may be spaced apart from each other in the second direction (e.g., direction D2 or direction D4) crossing the first direction. The auxiliary electrode SC may at least partially overlap a bank opening 29OP of the bank layer 29.

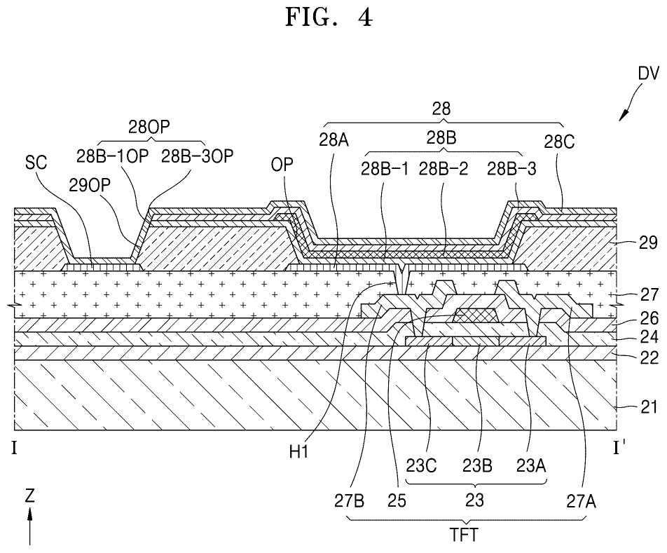

The auxiliary electrode SC may be in contact with an opposite electrode 28C (see FIG. 4) integrally or commonly formed to cover the display area DA. In a case where the display area DA has a relatively large area, current-resistance loss (or IR drop) may occur in the integrated opposite electrode 28C, and thus, luminance deviation may occur between the plurality of sub-pixels. Here, an electric signal may be transmitted through the auxiliary electrode SC that may be in contact with the opposite electrode 28C and have high electric conductivity, and thus, IR drop that may occur in the opposite electrode 28C when no auxiliary electrode SC is provided may be effectively prevented.

The bank layer 29 may be arranged in the display area DA. The bank layer 29 may be provided with the pixel opening OP and the bank opening 29OP, which are defined or formed therethrough. The pixel opening OP of the bank layer 29 may expose at least some of pixel electrodes of the sub-pixels, thereby defining the emission regions of the sub-pixels. The bank opening 29OP of the bank layer 29 overlaps the auxiliary electrode SC to connect the auxiliary electrode SC to the opposite electrode 28C. The pixel opening OP and the bank opening 29OP of the bank layer 29 may have a shape formed by removing at least some of materials forming the bank layer 29. The pixel opening OP and the bank opening 29OP may have any shape, such as a circle, an oval, or a quadrangle.

According to an embodiment, the bank opening 29OP may be arranged in the unit pixel area UA. The bank opening 29OP may be arranged in some of the unit pixel areas UA and the bank opening 29OP may not be arranged in the remaining unit pixel areas UA. In an embodiment, for example, as shown in FIG. 3, the bank opening 29OP may be arranged in the second unit pixel area UA2, and the bank opening 29OP may not be arranged in the first, third, and fourth unit pixel areas UA1, UA3, and UA4. Embodiments are not limited thereto, and the bank opening 29OP may be arranged in all unit pixel areas UA.

The bank opening 29OP may be arranged at a location surrounded by the first to fourth sub-pixels P1 to P4 arranged in the unit pixel area UA. In an embodiment, for example, in the unit pixel area UA, the first to fourth sub-pixels P1 to P4 may be arranged at vertices of an imaginary rectangle surrounding the bank opening 29OP. The bank opening 29OP may be arranged in some of the unit pixel areas UA. Accordingly, the first sub-pixel P1, the bank opening 29OP, and the fourth sub-pixel P4 may be arranged in the third direction (direction D3). The second sub-pixel P2, the bank opening 29OP, and the third sub-pixel P3 may be arranged in the fourth direction (direction D4).

According to an embodiment, a sub-pixel adjacent to the bank opening 29OP may have a shape in which one region is cut based on a shape of the bank opening 29OP. One side of the sub-pixel adjacent to the bank opening 29OP may have a line corresponding to the bank opening 29OP. In an embodiment, for example, where the bank opening 29OP is a circle as shown in FIG. 3, a portion of an edge of the second sub-pixel P2, which is adjacent to the bank opening 29OP, and a portion of an edge of the third sub-pixel P3, which is adjacent to the bank opening 29OP, may each be curved in a shape surrounding the bank opening 29OP that is a circle. Alternatively, the portions may be in a straight line having an angle corresponding to the bank opening 29OP. In an embodiment, although not shown in FIG. 3, a portion of an edge of the first sub-pixel P1, which is adjacent to the bank opening 29OP, and a portion of an edge of the fourth sub-pixel P4, which is adjacent to the bank opening 29OP, may each be cut.

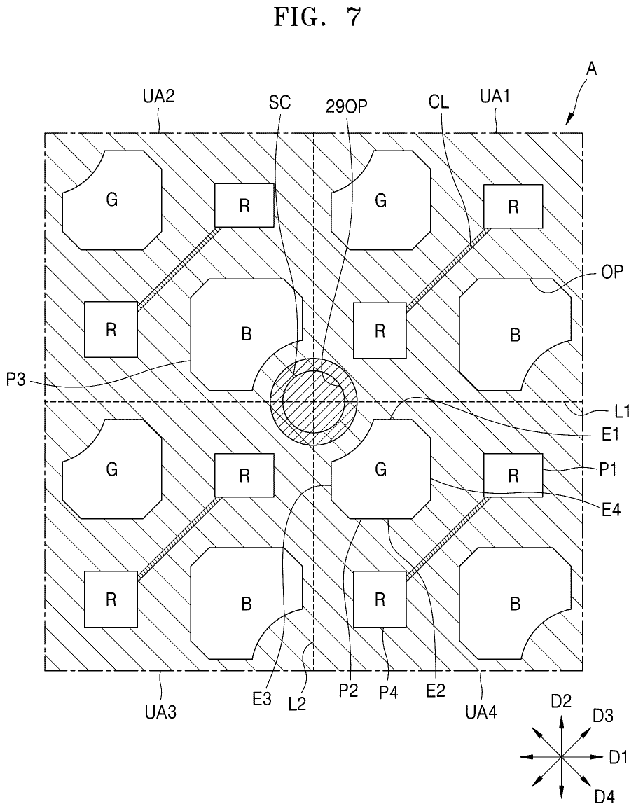

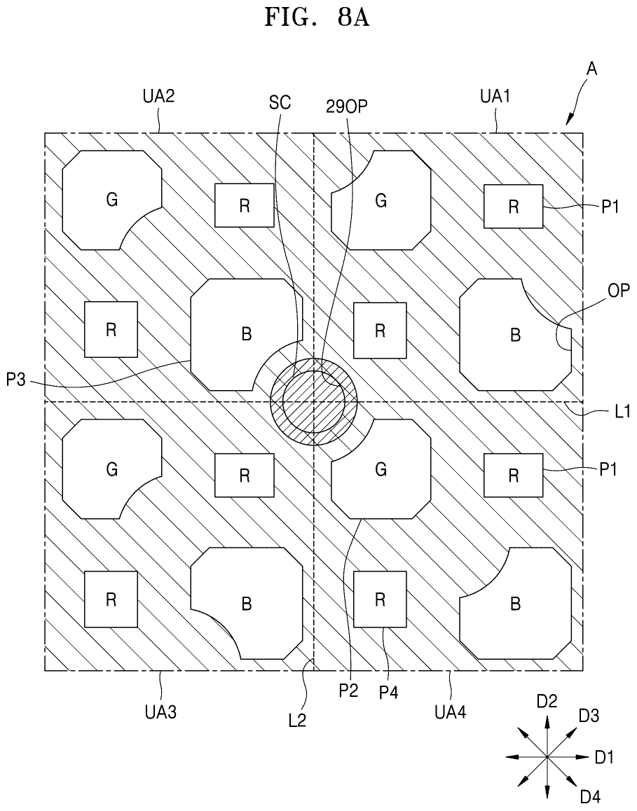

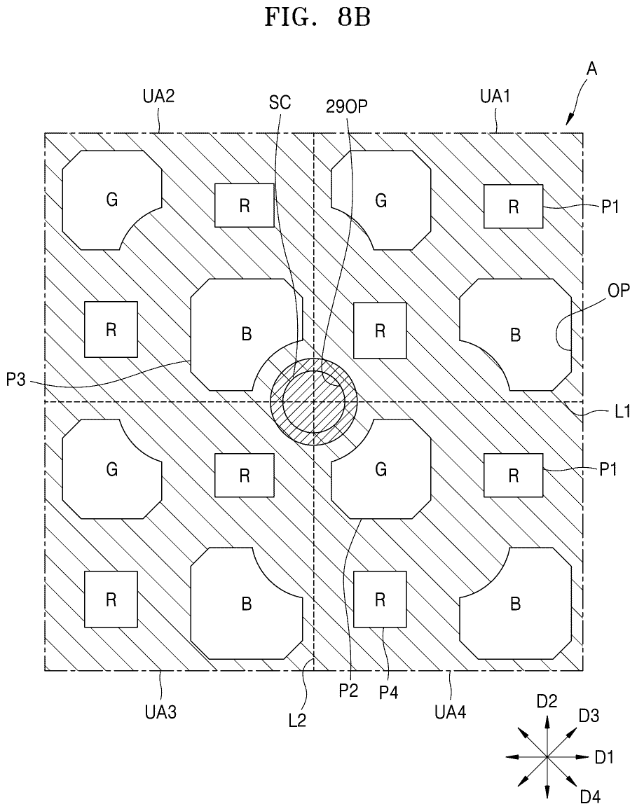

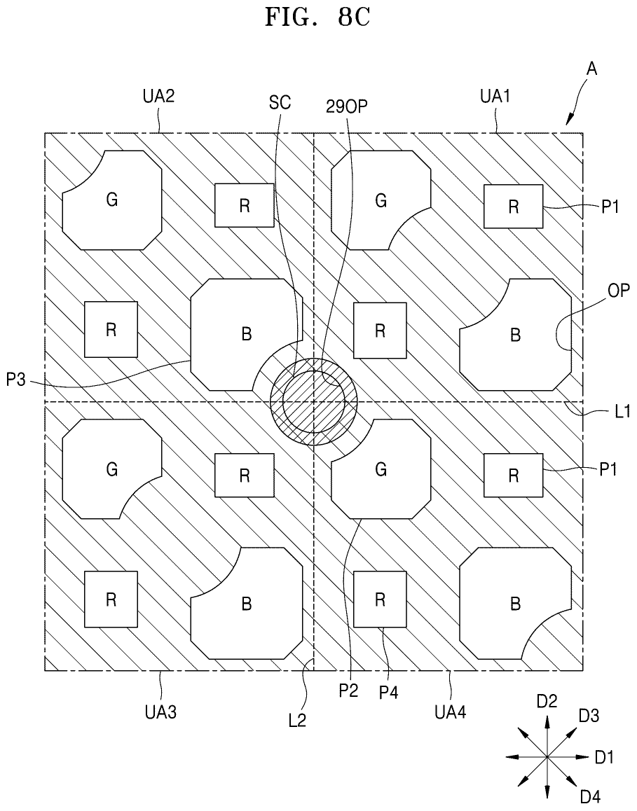

According to an embodiment, a shape of a sub-pixel included in the unit pixel area UA including the bank opening 29OP may be a shape from which one region is removed for an arrangement of the bank opening 29OP, compared to a shape of a sub-pixel included in the unit pixel area UA not including the bank opening 29OP. In an embodiment, for example, a shape of the second sub-pixel P2 of the second unit pixel area UA2 including the bank opening 29OP may be a shape from which one region adjacent to the bank opening 29OP is cut, compared to a shape of the first unit pixel area UA1 not including the bank opening 29OP. An opening ratio loss may be reduced by only adjusting a shape of a sub-pixel of the unit pixel area UA where the bank opening 29OP is arranged. However, embodiments are not limited thereto. As will be described below with reference to FIGS. 7 and 8A to 8C, areas (or shapes) of sub-pixels that emits a same color light may be the same as each other.

In general, when the first to fourth sub-pixels P1 to P4 are arranged in the unit pixel area UA, the non-pixel area in the unit pixel area UA may be relatively small. According to an embodiment, the bank opening 29OP is arranged to be surrounded by the sub-pixels while adjusting a shape of a sub-pixel adjacent to the bank opening 29OP, and thus, IR drop may be effectively prevented in a relatively small non-pixel area without providing an additional space between the unit pixel areas UA or the like.

A connecting wire CL may be arranged in the unit pixel area UA. The connecting wire CL may be a wire connecting the first sub-pixel P1 and the fourth sub-pixel P4, which emit a same color light, to each other. One end of the connecting wire CL may be connected to the pixel electrode of the first sub-pixel P1 and the other end thereof may be connected to the pixel electrode of the fourth sub-pixel P4. The connecting wire CL is connected to a pixel circuit such that the first sub-pixel P1 and the fourth sub-pixel P4 are drive by a same pixel circuit. The connecting wire CL may be a separate wire connecting the first sub-pixel P1 and the fourth sub-pixel P4 to each other. Alternatively, the connecting wire CL may be regions of the pixel electrode of the first sub-pixel P1 and the pixel electrode of the fourth sub-pixel P4, which are integrated.

According to an embodiment, where the bank opening 29OP is provided between the first sub-pixel P1 and the fourth sub-pixel P4 as shown in FIG. 3, the connecting wire CL may extend around the bank opening 29OP. According to an embodiment, the connecting wire CL may include a transparent conducting oxide (TCO). The connecting wire CL may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to an embodiment, the connecting wire CL may include poly-ITO. The connecting wire CL includes TCO, and thus, transmissivity of the unit pixel area UA may be increased.

FIG. 4 is a cross-sectional view schematically illustrating a display device 20 taken along line I-I′ of FIG. 3, according to an embodiment. A stack structure of the display device 20, according to an embodiment, will be briefly described with reference to the cross-sectional view of FIG. 4.

Referring to FIG. 4, the display device 20, according to an embodiment, may include a display layer disposed on a substrate 21. The display layer may include a thin-film transistor TFT and an organic light-emitting diode 28. Here, the thin-film transistor TFT may correspond to the driving transistor M1 of the pixel circuit PC of FIG. 2 and the organic light-emitting diode 28 may correspond to the light-emitting diode LED of FIG. 2. The thin-film transistor TFT may be disposed on the substrate 21, a passivation layer 27 may be arranged to cover the thin-film transistor TFT, and the organic light-emitting diode 28 may be disposed on the passivation layer 27.

The substrate 21 may include an insulating material, such as glass, quartz, or a polymer resin. The substrate 21 may be a rigid substrate or a flexible substrate capable of being bent, folded, or rolled. In an embodiment, for example, the substrate 21 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 21 may have a multi-layer structure including a layer including the polymer resin and an inorganic layer (not shown). In an embodiment, for example, the substrate 21 may include two layers including the polymer resin and an inorganic barrier layer therebetween.

A buffer layer 22 including an organic compound and/or an inorganic compound may be further disposed on a top surface of the substrate 21. In an embodiment, for example, the buffer layer 22 may include SiOx (x≥1) and/or SiNx (x≥1).

In an embodiment, a semiconductor layer 23 arranged in a certain pattern may be disposed on the buffer layer 22, and the semiconductor layer 23 may be embedded by or covered with a gate insulating layer 24. The semiconductor layer 23 includes a source region 23A and a drain region 23C, and further includes a channel region 23B therebetween.

The semiconductor layer 23 may include at least one selected from various materials. In an embodiment, for example, the semiconductor layer 23 may include an inorganic semiconductor material such as amorphous silicon or crystalline silicon. In an embodiment, for example, the semiconductor layer 23 may include an oxide semiconductor. In an embodiment, for example, the semiconductor layer 23 may include an organic semiconductor material. The source region 23A and the drain region 23C of the semiconductor layer 23 may be doped with an impurity, according to a type of a thin-film transistor, such as a driving thin-film transistor or a switching thin-film transistor.

The gate insulating layer 24 may be arranged between the semiconductor layer 23 and a gate electrode 25. The gate insulating layer 24 may include an inorganic insulating material, such as silicon nitride, silicon oxide, and/or silicon oxynitride.

The gate electrode 25 corresponding to the semiconductor layer 23 and an interlayer insulating layer 26 embedding or covering the gate electrode 25 are disposed on a top surface of the gate insulating layer 24. The gate electrode 25 may overlap the channel region 23B of the semiconductor layer 23. The gate electrode 25 may include molybdenum (Mo), copper (Cu), or titanium (Ti), and may have a single-layer or multi-layer structure including such a material. The interlayer insulating layer 26 may cover the gate electrode 25. The interlayer insulating layer 26 may be an inorganic layer including silicon oxynitride, silicon oxide, or silicon nitride. The interlayer insulating layer 26 may be a single layer or a multi-layer.

A source electrode 27A and a drain electrode 27B may be disposed on the interlayer insulating layer 26. The source electrode 27A and the drain electrode 27B may include aluminum (AI), Cu, or Ti. According to an embodiment, the source electrode 27A and the drain electrode 27B may have a multi-layer structure of Ti/Al/Ti. The source electrode 27A and the drain electrode 27B may be respectively connected to the source region 23A and the drain region 23C of the semiconductor layer 23 through a contact hole.

The passivation layer 27 is disposed on the thin-film transistor TFT provided as such, and a pixel electrode 28A (or a first electrode) of the organic light-emitting diode 28 is disposed on the passivation layer 27. The pixel electrode 28A is in contact with the drain electrode 27B of the thin-film transistor TFT through a contact hole H1 defined or formed in the passivation layer 27. According to another embodiment, the pixel electrode 28A may be in contact with the source electrode 27A. The passivation layer 27 may include an inorganic material and/or an organic material, and may include a single layer or two or more layers. The passivation layer 27 may be a planarization layer having a flat top surface regardless of a curve of a layer below, or may be curved according to the curve of the layer below.

The pixel electrode 28A may include a conductive oxide, such as ITO, IZO, ZnO, In₂O₃, IGO, or AZO. The pixel electrode 28A may include a reflective layer including silver (Ag), magnesium (Mg), Al, platinum (Pt), palladium (Pd), gold (Au), nickel (Ni), neodymium (Nd), iridium (Ir), chromium (Cr), or a compound thereof. In an embodiment, for example, the pixel electrode 28A may have a structure including a layer formed of ITO, IZO, ZnOₓ, or In₂O₃, on/below the reflective layer. In an embodiment, for example, the pixel electrode 28A may have a stack structure of ITO/Ag/ITO.

The auxiliary electrode SC and the pixel electrode 28A may be disposed on the passivation layer 27 while being spaced apart from each other. The auxiliary electrode SC may include a same material as the pixel electrode 28A by being formed through a same process and of the same material as the pixel electrode 28A. The auxiliary electrode SC may be in contact with the opposite electrode 28C described below. The auxiliary electrode SC may be in contact with the opposite electrode 28C through an intermediate opening 28OP formed in a first auxiliary layer 28B-1 and a second auxiliary layer 28B-3.

In an embodiment, the pixel electrode 28A and the auxiliary electrode SC may be disposed on the passivation layer 27, and the bank layer 29 may be formed by an organic material and/or an inorganic material to cover the pixel electrode 28A and the passivation layer 27, where the bank layer 29 covers edges of the pixel electrode 28A and the auxiliary electrode SC, and the pixel electrode 28A is exposed through an opening region. In other words, the bank layer 29 may be provided with the pixel opening OP defined therethrough to expose a portion of the pixel electrode 28A and the bank opening 29OP defined therethrough to expose a portion of the auxiliary electrode SC. The pixel opening OP may overlap a center portion of the pixel electrode 28A, and the bank opening 29OP may overlap a center portion of the auxiliary electrode SC. The bank opening 29OP of the bank layer 29 may be simultaneously formed with the pixel opening OP through a same process as the pixel opening OP, or may be simultaneously formed with the intermediate opening 28OP of an intermediate layer 28B through a same process as the intermediate opening 28OP.

According to an embodiment, the auxiliary electrode SC may be provided between a plurality of insulating layers disposed below the bank layer 29. In such an embodiment, the insulating layers stacked on the auxiliary electrode SC may be provided with an opening defined therethrough to overlap the bank opening 29OP. In an embodiment, for example, where the auxiliary electrode SC is disposed on the interlayer insulating layer 26, the passivation layer 27 may be provided with an opening defined therethrough to overlap the bank opening 29OP such that the opposite electrode 28C and the auxiliary electrode SC are in contact with each other.

The intermediate layer 28B and the opposite electrode 28C are disposed on the pixel electrode 28A. The opposite electrode 28C may be provided throughout the display area DA. The opposite electrode 28C may be disposed on the intermediate layer 28B and the bank layer 29. Hereinafter, for convenience of description, embodiments where the opposite electrode 28C is disposed on the intermediate layer 28B and the bank layer 29 will be described in detail.

The pixel electrode 28A may function as an anode and the opposite electrode 28C may function as a cathode, or vice versa. The pixel electrode 28A and the opposite electrode 28C are insulated from each other by the intermediate layer 28B, and an organic emission layer may emit light when voltages of different polarities are applied to the intermediate layer 28B.

The intermediate layer 28B may include an organic emission layer 28B-2. In an embodiment, for example, the intermediate layer 28B may include the organic emission layer 28B-2 and further include at least one selected from the first auxiliary layer 28B-1 or the second auxiliary layer 28B-3. In an embodiment, the first auxiliary layer 28B-1 may include at least one of a hole injection layer or a hole transport layer, and the second auxiliary layer 28B-3 may include at least one of an electron transport layer or an electron injection layer. In such an embodiment, the first auxiliary layer 28B-1 may be provided between the organic emission layer 28B-2 and the pixel electrode 28A, and the second auxiliary layer 28B-3 may be provided between the organic emission layer 28B-2 and the opposite electrode 28C. However, the embodiments are not limited thereto, and the intermediate layer 28B may include the organic emission layer 28B-2 and further include other various functional layers (not shown). Hereinafter, for convenience of description, embodiments where the intermediate layer 28B includes the first auxiliary layer 28B-1, the organic emission layer 28B-2, and the second auxiliary layer 28B-3 will be described in detail.

In an embodiment, the intermediate layers 28B may be provided in plural, where at least one intermediate layer 28B is spaced apart from the other intermediate layers 28B. In an embodiment, for example, the organic emission layers 28B-2 may be spaced apart from each other throughout of the display area DA. In such an embodiment, the organic emission layers 28B-2 may be arranged to respectively correspond to the sub-pixels, and the sub-pixels may emit light of different colors according to materials of the organic emission layers 28B-2. In another embodiment, at least one of the first auxiliary layers 28B-1 or the second auxiliary layers 28B-3 may be spaced apart from each other to correspond to the organic emission layers 28B-2. In another embodiment, the organic emission layers 28B-2 may be spaced apart from each other, and at least one of the first auxiliary layers 28B-1 or the second auxiliary layers 28B-3 may be arranged to cover an entire surface of the display area DA. Hereinafter, for convenience of description, embodiments where the organic emission layers 28B-2 are spaced apart from each other to form a pattern in the display area DA, and the first auxiliary layers 28B-1 and the second auxiliary layers 28B-3 are arranged throughout the display area DA will be described in detail.

In an embodiment, the intermediate layer 28B may be provided with the intermediate opening 28OP defined therethrough to expose a portion of the auxiliary electrode SC to allow the auxiliary electrode SC and the opposite electrode 28C to be in contact with each other. In an embodiment, the organic emission layers 28B-2 of the intermediate layer 28B may be spaced apart from each other for each sub-pixel, and the first auxiliary layer 28B-1 and the second auxiliary layer 28B-3 may be provided with the intermediate opening 28OP. The intermediate opening 28OP may include a first auxiliary layer opening region 28B-1OP of the first auxiliary layer 28B-1, and a second auxiliary layer opening region 28B-3OP of the second auxiliary layer 28B-3. The first auxiliary layer opening region 28B-1OP, the second auxiliary layer opening region 28B-3OP, and the bank opening 29OP may overlap each other, and the auxiliary electrode SC may be exposed in a corresponding overlapping region.

The opposite electrode 28C may be disposed on the intermediate layer 28B. The opposite electrode 28C may include a conductive material with a low work function. In an embodiment, for example, the opposite electrode 28C may include a (semi-) transparent layer including Ag, Mg, Al, Pt, Pd, Au, Ni, Nd, Ir, Cr, lithium (Li), calcium (Ca), or an alloy thereof. The opposite electrode 28C may further include a layer including ITO, IZO, ZnO, or In₂O₃, on the (semi-) transparent layer including the above material. In an embodiment, the opposite electrode 28C may be integrally or commonly formed to correspond to the organic light-emitting diodes 28 included in the display area DA.

An upper portion of the auxiliary electrode SC arranged in a non-pixel area between the sub-pixels may be exposed by the bank opening 29OP of the bank layer 29 and the intermediate opening 28OP of the intermediate layer 28B, and thus, the auxiliary electrode SC and the opposite electrode 28C may be in contact with each other in a region where the intermediate opening 28OP and the bank opening 29OP overlap each other. Accordingly, resistance of the opposite electrode 28C may be reduced, thereby reducing occurrence of IR drop. In an embodiment, for example, where the opposite electrode 28C is substantially thin, resistance of the opposite electrode 28C is increased, and thus, degree of IR drop may be increased. In such an embodiment, the auxiliary electrode SC is connected to the opposite electrode 28C, thereby reducing the resistance of the opposite electrode 28C.

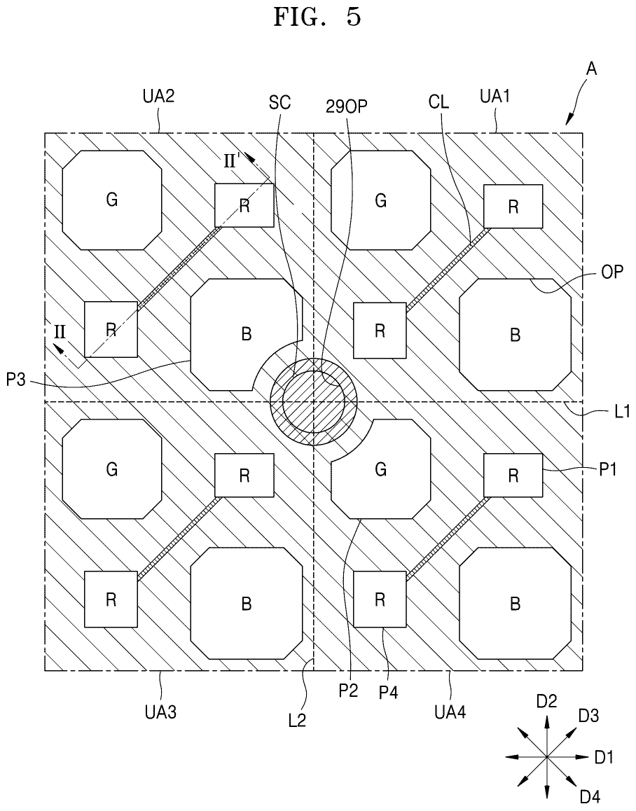

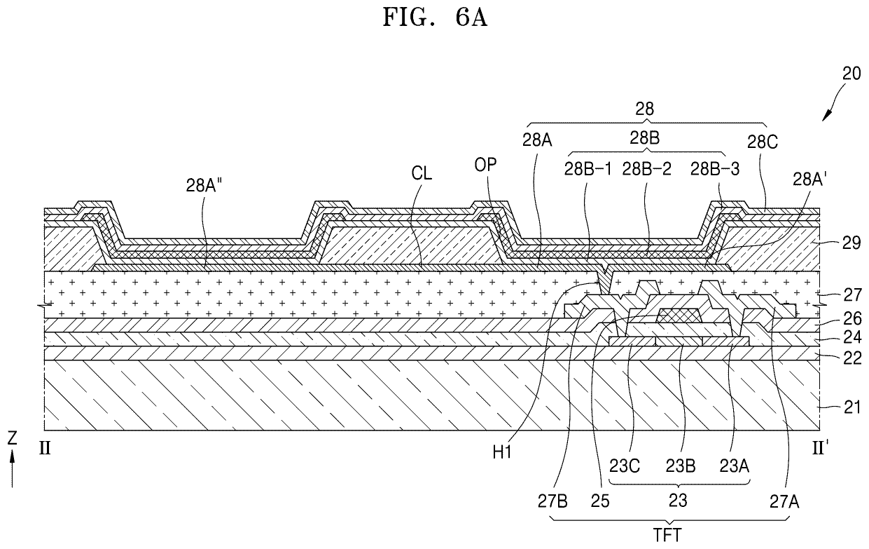

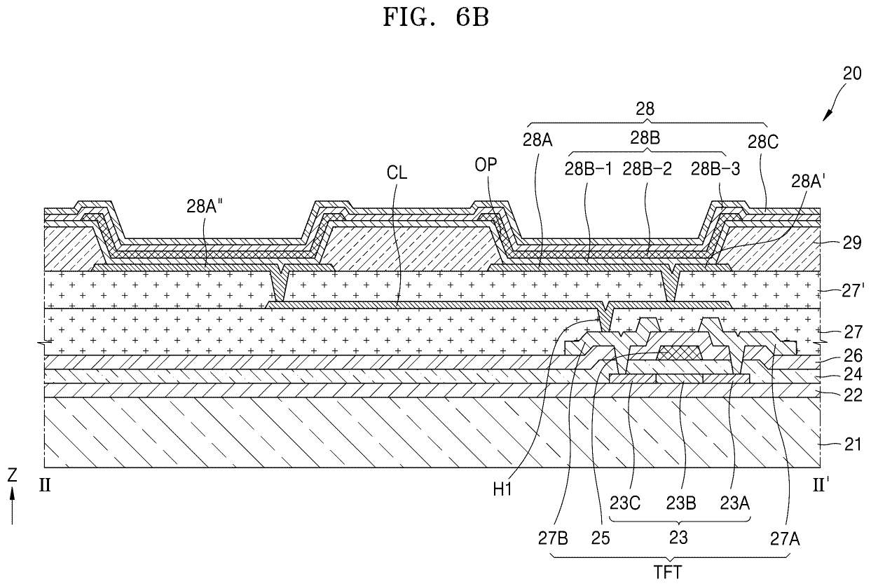

FIG. 5 is a plan view schematically illustrating the portion A of the display device DV, according to an embodiment, and FIGS. 6A and 6B are cross-sectional views schematically illustrating the display device 20 taken along line II-II′ of FIG. 5. Components of FIG. 5, which are labeled with same reference numerals as those of FIG. 3, denote same components, and thus, any repetitive detailed descriptions thereof will be omitted and differences will be mainly described.

Referring to FIG. 5, in an embodiment, the unit pixel area UA includes the first unit pixel area UA1, the second unit pixel area UA2, the third unit pixel area UA3, and the fourth unit pixel area UA4, which form quadrants, and the bank opening 29OP of the bank layer 29 may be positioned at an origin portion of the quadrants. The origin portion is a region near a point where horizontal axes and vertical axes forming the quadrants are met or a center portion of four adjacent unit pixel areas UA arranged in a two-by-two matrix form.

The bank opening 29OP may overlap all of the first to fourth unit pixel areas UA1 to UA4. The bank opening 29OP may be surrounded by the fourth sub-pixel P4 of the first unit pixel area UA1, the third sub-pixel P3 of the second unit pixel area UA2, the first sub-pixel P1 of the third unit pixel area UA3, and the second sub-pixel P2 of the fourth unit pixel area UA4.

Sub-pixels adjacent to the bank opening 29OP may have a shape in which one region is cut based on a shape of the bank opening 29OP. In an embodiment, for example, referring to FIG. 5, a portion of an edge of the third sub-pixel P3 of the second unit pixel area UA2, which is adjacent to the bank opening 29OP, may be curved in a shape surrounding the bank opening 29OP that is a circle. Alternatively, the portion may be in a straight line having an angle corresponding to the bank opening 29OP. A portion of an edge of the second sub-pixel P2 of the fourth unit pixel area UA4, which is adjacent to the bank opening 29OP, may be curved in a shape surrounding the bank opening 29OP that is a circle. Alternatively, the portion may be in a straight line having an angle corresponding to the bank opening 29OP. In an embodiment, although not shown in FIG. 5, a portion of an edge of the fourth sub-pixel P4 of the first unit pixel area UA1, which is adjacent to the bank opening 29OP, and a portion of an edge of the first sub-pixel P1 of the third unit pixel area UA3, which is adjacent to the bank opening 29OP, may be cut.

Referring to FIG. 5, the connecting wire CL may extend in the third direction (direction D3) in which the first sub-pixel P1 and the fourth sub-pixel P4 are arranged. The connecting wire CL may be provided in a straight line connecting the first sub-pixel P1 and the fourth sub-pixel P4 to each other. The connecting wire CL may cross between the second sub-pixel P2 and the third sub-pixel P3 in the unit pixel area UA. The connecting wire CL may extend while crossing a center portion of the unit pixel area UA, in the unit pixel area UA. According to an embodiment, the bank opening 29OP is arranged in a center portion where the plurality of unit pixel areas UA are in contact, the connecting wire CL may extend and connect the first sub-pixel P1 and the fourth sub-pixel P4 to each other without having to detour around the bank opening 29OP. Accordingly, a wiring design may be simplified.

Referring to FIG. 6A, in the unit pixel area UA, a first pixel electrode 28A′ of the first sub-pixel P1 and a fourth pixel electrode 28A″ of the fourth sub-pixel P4 may be integrally formed as a single unitary and indivisible part. In this case, the connecting wire CL includes a same material as the pixel electrode 28A and may denote a portion of the pixel electrode 28A. The first pixel electrode 28A′ and the fourth pixel electrode 28A″ may be formed as one pixel electrode 28A to simplify processes.

Referring to FIG. 6B, in an embodiment, the connecting wire CL may be provided separately from the first pixel electrode 28A′ of the first sub-pixel P1 and the fourth pixel electrode 28A″ of the fourth sub-pixel P4. According to an embodiment, a sub-layer 27′ may be disposed on the passivation layer 27, and the connecting wire CL may be provided between the passivation layer 27 and the sub-layer 27′. Each of the first pixel electrode 28A′ and the fourth pixel electrode 28A″ may be connected to the connecting wire CL through a contact hole. Accordingly, the connecting wire CL may enable the first sub-pixel P1 and the fourth sub-pixel P4 in the unit pixel area UA to be driven by a same signal.

FIG. 7 is a plan view schematically illustrating the portion A of the display device DV, according to an embodiment, and FIGS. 8A to 8C are plan views schematically illustrating the portion A of the display device DV, according to an embodiment. Components of FIGS. 7 to 8C, which are labeled with same reference numerals as those of FIGS. 3 and 5, denote same components, and thus, any repetitive detailed descriptions thereof will be omitted and differences will be mainly described.

In an embodiment, as described above with reference to FIG. 5, the third sub-pixel P3 of the second unit pixel area UA2 and the third sub-pixel P3 of the first unit pixel area UA1 have different areas, according to a position of the bank opening 29OP. In such an embodiment, compared to the third sub-pixel P3 of the first unit pixel area UA1, the third sub-pixel P3 of the second unit pixel area UA2 has a shape in which one region adjacent to the bank opening 29OP is cut. According to an arrangement of the bank opening 29OP, an opening ratio may be reduced only for some sub-pixels.

Referring to FIG. 7, in an embodiment, sub-pixels that emit a same color light may have a same area as each other. In an embodiment, for example, an area of the third sub-pixel P3 of the second unit pixel area UA2, which is adjacent to the bank opening 29OP, may be the same as an area of the third sub-pixel P3 of the first unit pixel area UA1, an area of the third sub-pixel P3 of the third unit pixel area UA3, and an area of the third sub-pixel P3 of the fourth unit pixel area UA4, which are not adjacent to the bank opening 29OP. In such an embodiment, an area of the second sub-pixel P2 of the fourth unit pixel area UA4, which is adjacent to the bank opening 29OP, may be the same as areas of the second sub-pixels P2 that are not adjacent to the bank opening 29OP.

In an embodiment where a sub-pixel adjacent to the bank opening 29OP has an area different from other sub-pixels that emit a same color light as the sub-pixel, a life span of a certain pixel may not be the same as life spans of adjacent pixels. According to an embodiment, a sub-pixel adjacent to the bank opening 29OP has a same area as sub-pixels that emit a same color light as the sub-pixel and not adjacent to the bank opening 29OP, and thus, IR drop may be effectively prevented and life span of the sub-pixels may become substantially uniform.

Referring to FIG. 7, sub-pixels that emit a same color light have a same shape arranged in a same direction. In an embodiment, for example, the second sub-pixel P2 of the fourth unit pixel area UA4 is provided in a shape in which one region is dented according to a position of the bank opening 29OP, and the second sub-pixels P2 of the first to third unit pixel areas UA1 to UA3, which are adjacent thereto, also have a same shape as the second sub-pixel P2 of the fourth unit pixel area UA4. The second sub-pixel P2 has a shape in which one region is cut, and thus, portions of an edge of the second sub-pixel P2 extending in the first direction (D1 direction) or the second direction (D2 direction) may have different lengths. In such an embodiment, the edge of the second sub-pixel P2 may have a first side E1 and a second side E2, which extend in the first direction (D1 direction), and a third side E3 and a fourth side E4, which extend in the second direction (D2 direction). The first side E1 may be shorter than the second side E2, and the third side E3 may be shorter than the fourth side E4. Accordingly, regarding characteristics of a viewing angle, vertical or horizontal symmetry may not be provided.

Referring to FIGS. 8A to 8C, according to an embodiment, sub-pixels that emit a same color light may have shapes in which certain shapes are symmetric or rotated. In an embodiment, referring to the second sub-pixel P2 shown in FIG. 8A, the second sub-pixel P2 of the fourth unit pixel area UA4 has a certain shape (hereinafter, a first shape), and the second sub-pixel P2 of the first unit pixel area UA1 also has the first shape. In such an embodiment, the second sub-pixels P2 of the second unit pixel area UA2 and the third unit pixel area UA3 have shapes in which the first shape is rotated 180° clockwise.

Referring to FIG. 8B, in an embodiment, the second sub-pixel P2 of the first unit pixel area UA1 may have a shape in which the first shape is reversed based on the horizontal axis L1, the second sub-pixel P2 of the second unit pixel area UA2 may have a shape in which the first shape is rotated 180°, and the second sub-pixel P2 of the third unit pixel area UA3 may have a shape in which the first shape is reversed based on the vertical axis L2. In an embodiment, referring to FIG. 8C, the second sub-pixel P2 of the first unit pixel area UA1 may have a shape in which the first shape is rotated 180°, the second sub-pixel P2 of the second unit pixel area UA2 may have a same shape as the first shape, and the second sub-pixel P2 of the third unit pixel area UA3 may have a shape in which the first shape is rotated 180°. As described above, the second sub-pixels P2 that are arranged in adjacent unit pixel areas UA and emit a same color light may have shapes in which the first shape is rotated or reversed. Accordingly, locations of the first side E1 and the second side E2 may be switched, and locations of the third side E3 and the fourth side E4 may be switched. Also, a region cut by the bank opening 29OP may be mixed and arranged in the unit pixel area UA.

A viewing angle of the display device DV may change according to a length of an edge of a sub-pixel. According to an embodiment, arrangement directions of sub-pixels included in the unit pixel area UA may be changed and the sub-pixels may be arranged (designed) by combining the modification of shapes of the sub-pixels as described above, thereby improving viewing angle characteristics.

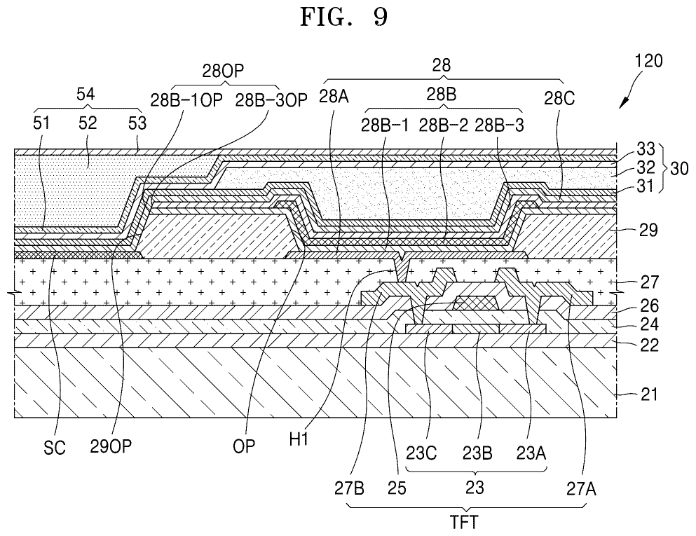

FIG. 9 is a cross-sectional view schematically illustrating a portion of a display device 120, according to an embodiment. Components of FIG. 9, which are labeled with same reference numerals as those of FIG. 4, denote same components, and thus, any repetitive detailed descriptions thereof will be omitted and differences will be mainly described.

In an embodiment, an encapsulation layer 30 may be disposed on the opposite electrode 28C. The encapsulation layer 30 may include at least one inorganic encapsulation layer and at least one organic encapsulation layer. According to an embodiment, FIG. 9 illustrates the encapsulation layer 30 including a first inorganic encapsulation layer 31, a second inorganic encapsulation layer 33, and a first organic encapsulation layer 32 between the first inorganic encapsulation layer 31 and the second inorganic encapsulation layer 33.

The first and second inorganic encapsulation layers 31 and 33 may each include at least one inorganic insulating material. The inorganic insulating material may include aluminum oxide, titanium oxide, tantalum oxide, hafnium oxide, zinc oxide, silicon oxide, silicon nitride, and/or silicon oxynitride.

The first organic encapsulation layer 32 may include a polymer-based material. Examples of the polymer-based material may include an acrylic resin, an epoxy resin, polyimide, and polyethylene. In an embodiment, for example, the first organic encapsulation layer 32 may include acrylic resin, such as polymethyl methacrylate, polyacrylic acid, or the like. The first organic encapsulation layer 32 may be formed by curing monomer or applying polymer.

The input detecting portion (not shown) may be disposed on the encapsulation layer 30. The input detecting portion may include a plurality of conducting layers and detection insulating layers, where the conducting layers include detection sensors that detects an external input signal.

A planarizing portion 54 may be further disposed on the encapsulation layer 30. The planarizing portion 54 may include a first planarization inorganic layer 51, a first planarization organic layer 52, and a second planarization inorganic layer 53. The planarizing portion 54 may include at least one of the first planarization inorganic layer 51 or the second planarization inorganic layer 53. The first planarization organic layer 52 may include an organic material and formed through a solution process, such as spin coating, slit coating, or inkjet process.

The planarizing portion 54 may be provided between a display layer and the input detecting portion. In an embodiment, the planarizing portion 54 may be provided in a partial region between the input detecting portion and the encapsulation layer 30 covering display elements. The first planarization organic layer 52 covers a portion of the display layer. According to an embodiment, the first planarization organic layer 52 may be disposed on a region where the intermediate opening 28OP is arranged. The first planarization organic layer 52 may be arranged to fill openings of upper layers of the auxiliary electrode SC for exposing a partial region of the auxiliary electrode SC, and compensate for a step difference between the display layer and the input detecting portion. In an embodiment, to expose a partial region of the auxiliary electrode SC, the bank layer 29 disposed on the auxiliary electrode SC is provided with the bank opening 29OP defined therethrough to overlap a center portion of the auxiliary electrode SC, and the intermediate layer 28B includes the intermediate opening 28OP, and thus, the first planarization organic layer 52 may fill the bank opening 29OP and the intermediate opening 28OP. Accordingly, the first planarization organic layer 52 may cover non-planarization surfaces defined by the bank opening 29OP and the intermediate opening 28OP, thereby planarizing the non-planarization surfaces. As a result, the display device 120 according to an embodiment stably provides a planarization surface even for a region where a portion of the auxiliary electrode SC is externally exposed, i.e., a region where an organic layer such as the bank layer 29 is not arranged, and thus, a high-quality image may be realized.

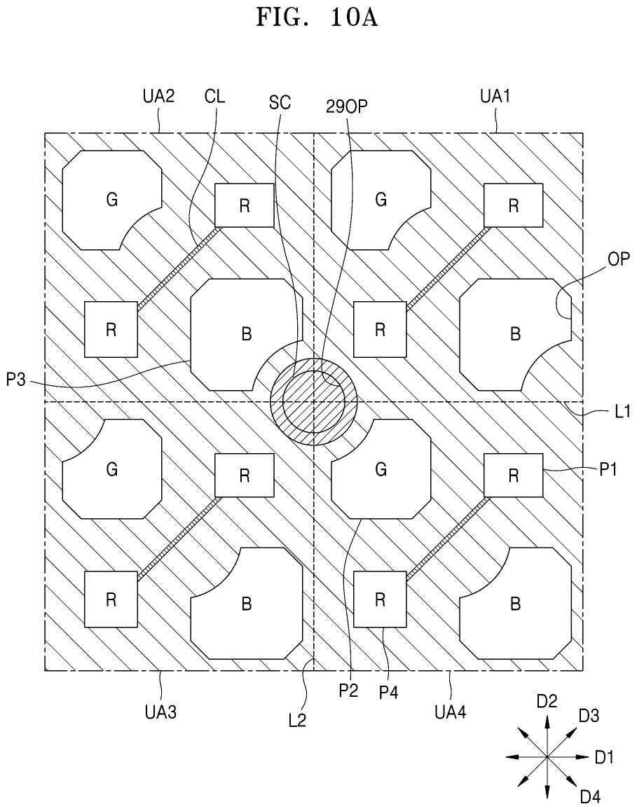

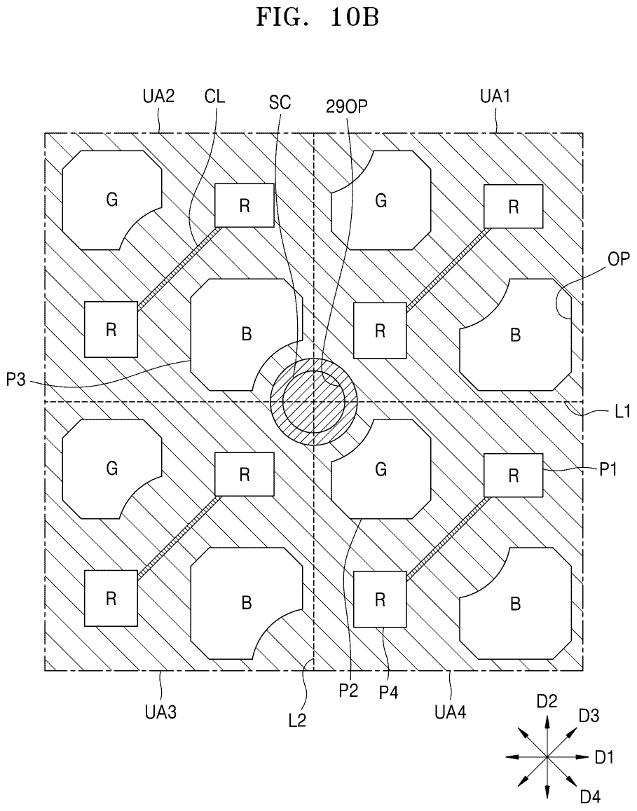

FIGS. 10A and 10B are plan views schematically illustrating a portion of a display device, according to an embodiment. Components of FIGS. 10A and 10B, which are labeled with same reference numerals those as FIGS. 5 and 7, denote same components, and thus, any repetitive detailed descriptions thereof will be omitted and differences will be mainly described.

In an embodiment, as described above with reference to FIG. 5, the connecting wire CL may be arranged in the unit pixel area UA. The connecting wire CL may be a wire connecting the first sub-pixel P1 and the fourth sub-pixel P4, which emit a same color, to each other. One end of the connecting wire CL may be connected to the pixel electrode of the first sub-pixel P1 and the other end thereof may be connected to the pixel electrode of the fourth sub-pixel P4.

In an embodiment, at least one of the first to fourth sub-pixels P1 to P4 may have a shape in which one region adjacent to the bank opening 29OP is cut. Referring to FIGS. 10A and 10B, according to an embodiment, the bank opening 29OP may be arranged at an origin portion of a imaginary quadrant defining the first to fourth unit pixel areas UA1 to UA4, and a shape of each of the third sub-pixel P3 of the second unit pixel area UA2 and the second sub-pixel P2 of the fourth unit pixel area UA4, which are arranged adjacent to the bank opening 29OP, may be cut such that the cut region thereof corresponds to a shape of the bank opening 29OP.

As described above with reference to FIGS. 7 to 8C, in addition to sub-pixels directly adjacent to the bank opening 29OP, sub-pixels that emit a same color light may have one region cut to have a same area as each other, for uniform life span between the sub-pixels. Also, for optical characteristic improvement (e.g., viewing angle improvement), the sub-pixels that emit a same color light may have a shape rotated and/or reversed based on a certain shape cut for an arrangement of the bank opening 29OP.

In an embodiment as described above, where shapes of sub-pixels are determined considering an arrangement of the bank opening 29OP, and optical characteristics and uniform lives between the sub-pixels, a shape of at least one selected from the second sub-pixel P2 and the third sub-pixel P3, which are adjacent to each other in one unit pixel area, may have one region adjacent to the connecting wire CL cut to correspond to a shape of the bank opening 29OP.

According to an embodiment, as shown in FIG. 10A, in the first unit pixel area UA1 and the second unit pixel area UA2, a lower right region of the second sub-pixel P2, adjacent to the connecting wire CL, is cut to correspond to a circular shape of the bank opening 29OP, and in the third unit pixel area UA3 and the fourth unit pixel area UA4, an upper left region of the third sub-pixel P3, adjacent to the connecting wire CL, is cut to correspond to the circular shape of the bank opening 29OP. According to an embodiment, as shown in FIG. 10B, in the second unit pixel area UA2 and the third unit pixel area UA3, the lower right region of the second sub-pixel P2, adjacent to the connecting wire CL, is cut to correspond to the circular shape of the bank opening 29OP, and in the first unit pixel area UA1 and the fourth unit pixel area UA4, the upper left region of the third sub-pixel P3, adjacent to the connecting wire CL, is cut to correspond to the circular shape of the bank opening 29OP.

According to an embodiment, as described with reference to FIGS. 10A and 10B, at least one selected from the second sub-pixel P2 and the third sub-pixel P3, which are adjacent to each other with the connecting wire CL therebetween in one unit pixel area, may have one region adjacent to the connecting wire CL cut, and accordingly, the connecting wire CL for electrically connecting the first sub-pixel P1 and the fourth sub-pixel P4 may be easily designed.

As described above, a display device according to embodiments of the invention may effectively prevent a voltage drop of an opposite electrode through an efficient pixel arrangement design, thereby improving uniformity of luminance.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate, on which unit pixel areas are defined, wherein the unit pixel areas are arranged in a first direction and a second direction perpendicular to the first direction, in a plan view;
a first sub-pixel, a second sub-pixel, a third sub-pixel, and a fourth sub-pixel, which are arranged on the substrate in each of the unit pixel areas, wherein the first sub-pixel emits light of a first color, the second sub-pixel emits light of a second color, the third sub-pixel emits light of a third color, and the fourth sub-pixel emits light of the first color;
a bank layer provided with a bank opening defined therein, wherein the bank opening is surrounded by the first sub-pixel, the second sub-pixel, the third sub-pixel, and the fourth sub-pixel, in the plan view;
an intermediate layer disposed on the bank layer, wherein an intermediate opening is defined in the intermediate layer to overlap the bank opening; and
an opposite electrode disposed on the intermediate layer.

2. The display device of claim 1, further comprising:
an auxiliary electrode disposed on the substrate,
wherein the opposite electrode is in contact with the auxiliary electrode through the intermediate opening and the bank opening.

3. The display device of claim 1, wherein, in the unit pixel areas, the first sub-pixel and the fourth sub-pixel are arranged adjacent to each other in a third direction crossing the first direction and the second direction, and the second sub-pixel and the third sub-pixel are arranged adjacent to each other in a fourth direction perpendicular to the third direction.

4. The display device of claim 1, wherein the bank opening is surrounded by the first to fourth sub-pixels arranged in one unit pixel area.

5. The display device of claim 1, wherein a shape of at least one selected from the first to fourth sub-pixels is obtained by cutting one region adjacent to the bank opening to correspond to a shape of the bank opening.

6. The display device of claim 1, wherein areas of second sub-pixels included in the unit pixel areas are the same as each other, and
areas of third sub-pixels included in the unit pixel areas are the same as each other.

7. The display device of claim 1, wherein shapes of second sub-pixels included in the unit pixel areas are the same as each other.

8. The display device of claim 1, wherein the unit pixel areas include a first unit pixel area, a second unit pixel area, a third unit pixel area, and a fourth unit pixel area, which form imaginary quadrants, and
the bank opening is positioned in an origin portion at which the first to fourth unit pixel areas all contact with each other.

9. The display device of claim 8, wherein the second sub-pixel included in the first unit pixel area has a first shape, and
a shape of at least one selected from second sub-pixels respectively included in the second to fourth unit pixel areas has a shape obtained by rotating the first shape in a certain angle or a shape obtained by reversing the first shape, based on a certain imaginary axis.

10. The display device of claim 1, wherein a pixel electrode of the first sub-pixel and a pixel electrode of the fourth sub-pixel are electrically connected to each other.

11. The display device of claim 10, further comprising:
a connecting wire extending in a third direction crossing the first direction and the second direction to connect the pixel electrode of the first sub-pixel and the pixel electrode of the fourth sub-pixel to each other.

12. The display device of claim 1, wherein the first color is red.

13. The display device of claim 1, wherein the unit pixel areas are provided in a lattice shape.

14. The display device of claim 1, further comprising:
an input detecting portion disposed on the opposite electrode; and
a planarizing portion arranged between the opposite electrode and the input detecting portion, and overlapping the bank opening.

15. A display device comprising:
A substrate on which unit pixel areas are defined, wherein the unit pixel areas are arranged in a first direction and a second direction perpendicular to the first direction, in a plan view;
an auxiliary electrode disposed on the substrate;
a first sub-pixel, a second sub-pixel, a third sub-pixel, and a fourth sub-pixel, which are arranged on the substrate in each of the unit pixel areas, wherein the first sub-pixel emits light of a first color, the second sub-pixel emits light of a second color, the third sub-pixel emits light of a third color, and the fourth sub-pixel emits light of the first color;
a bank layer provided with a bank opening defined therein, wherein the bank opening is surrounded by the first sub-pixel, the second sub-pixel, the third sub-pixel, and the fourth sub-pixel, in the plan view;
an intermediate layer disposed on the bank layer, wherein an intermediate opening is defined in the intermediate layer to overlap the bank opening; and
an opposite electrode in contact with the auxiliary electrode through the intermediate opening and the bank opening,
wherein a shape of at least one selected from the first to fourth sub-pixels is obtained by cutting one region adjacent to the bank opening to correspond to a shape of the bank opening.

16. The display device of claim 15, wherein the first sub-pixel and the second sub-pixel are alternately arranged in the first direction on a first row, and
the third sub-pixel and the fourth sub-pixel are alternately arranged in the first direction on a second row adjacent to the first row.

17. The display device of claim 16, wherein the unit pixel areas include a first unit pixel area, a second unit pixel area, a third unit pixel area, and a fourth unit pixel area, which form imaginary quadrants, and
the bank opening is positioned adjacent to a fourth sub-pixel of the first unit pixel area, a third sub-pixel of the second unit pixel area, a first sub-pixel of the third unit pixel area, and a second sub-pixel of the fourth unit pixel area.

18. The display device of claim 15, wherein areas of second sub-pixels included in the unit pixel areas are the same as each other, and
areas of third sub-pixels included in the unit pixel areas are the same as each other.

19. The display device of claim 15, wherein shapes of second sub-pixels included in the unit pixel areas are the same as each other, and
shapes of third sub-pixels included in the unit pixel areas are the same as each other.

20. The display device of claim 15, further comprising:
a connecting wire electrically connected to a pixel electrode of the first sub-pixel and a pixel electrode of the fourth sub-pixel and extending in a third direction crossing the first direction and the second direction diagonally,
wherein a shape of at least one selected from the second sub-pixel and the third sub-pixel, which are adjacent to each other in each of the unit pixel areas, has one region adjacent to the connecting wire cut to correspond to a shape of the bank opening.
